(19) United States
(12) Patent Application Publication
(10) Pub. No.: US 2025/0234654 A1
(43) Pub. Date: Jul. 17, 2025

(54) THROUGH-SILICON VIA STRUCTURE WITH ELECTROSTATIC DISCHARGE PROTECTION DIODE AND CIRCUIT

(71) Applicant: Winbond Electronics Corp., Taichung City (TW)

(72) Inventors: Jen-Hao HSIAO, Changhua County (TW); Chao-Lung WANG, Taichung City (TW)

(73) Assignee: Winbond Electronics Corp., Taichung City (TW)

(21) Appl. No.: 18/814,817

(22) Filed: Aug. 26, 2024

(30) Foreign Application Priority Data
Jan. 12, 2024 (TW) 113101373

(51) Int. Cl. H01L 27/02; H01L 21/768; H01L 23/48; H01L 29/861

(52) U.S. Cl. CPC H10D 89/931; H01L 21/76898; H01L 23/481; H10D 8/411

(57) ABSTRACT

A through-silicon via structure is provided. A semiconductor substrate has a first surface and a second surface, and the second surface is opposite to the first surface. A TSV extends from the first surface to the second surface of the semiconductor substrate. An N-type doped region surrounds the TSV and extends from the first surface to the second surface of the semiconductor substrate. A P-type well region is formed in the semiconductor substrate and surrounds the N-type doped region. A P-type doped region is formed in the P-type well region and surrounds the N-type doped region. The junction of the P-type well region and the N-type doped region forms an electrostatic discharge protection diode.

### CROSS REFERENCE TO RELATED APPLICATIONS

This Application claims priority of Taiwan Patent Application No. 113101373, filed on Jan. 12, 2024, the entirety of which is incorporated by reference herein.

### BACKGROUND OF THE INVENTION

### Field of the Invention

The present disclosure relates to a through-silicon via (TSV) structure, and, in particular, to a TSV structure with an electrostatic discharge protection diode.

### Description of the Related Art

Due to the continuous improvement of the integration density of various electronic components (e.g., transistors, diodes, resistors, capacitors, and the like.), semiconductor process nodes continue to be shrunk. With the increasing demand for miniaturization, high speed, large bandwidth, low power consumption, and low latency, the demands on semiconductor die packaging technology have also increased.

Three-dimensional (3D) circuits are a solution to the bottleneck in the development of two-dimensional circuits. Three-dimensional circuits use through-silicon vias as electrical connection paths to achieve wafer or die stack structures. Therefore, the length of metal wires and the resistance of wiring/trace can be reduced, and the die area can be decreased. As a result, three-dimensional circuits have the advantages of small size, high integration, high efficiency, low power consumption, and low cost.

Since electrostatic discharge causes damage to three-dimensional circuits, it is necessary to provide electrostatic discharge protection for silicon-through vias in the three-dimensional circuits.

### BRIEF SUMMARY OF THE INVENTION

An embodiment of the present disclosure provides a through-silicon via structure. The TSV structure includes a substrate having a first surface and a second surface. The second surface is opposite to the first surface. The TSV structure further includes a through-silicon via extending from the first surface to the second surface of the substrate, and an N-type doped region surrounding the through-silicon via and extending from the first surface to the second surface of the substrate. The TSV structure further includes a P-type well region formed in the substrate and surrounding the N-type doped region, and a P-type doped region formed in the P-type well region and surrounding the N-type doped region. The junction of the P-type well region and the N-type doped region forms an electrostatic discharge protection diode.

An embodiment of the present disclosure provides a circuit including a substrate and a plurality of through-silicon via structures. The substrate has a first surface and a second surface that is opposite to the first surface. Each of the plurality of through-silicon via structures includes a through-silicon via extending from the first surface to the second surface of the substrate, and an N-type doped region surrounding the through-silicon via and extending from the first surface to the second surface of the substrate. Each of the plurality of through-silicon via structures further includes a P-type well region formed in the substrate and surrounding the N-type doped region, and a P-type doped region formed in the P-type well region and surrounding the N-type doped region. The junction of the P-type well region and the N-type doped region forms an electrostatic discharge protection diode. The through-silicon via of a first through-silicon via structure of the plurality of through-silicon via structures is electrically connected to a power line, and the P-type doped region of the first through-silicon via structure is electrically connected to an input/output line. The through-silicon via of a second through-silicon via structure of the plurality of through-silicon via structures is electrically connected to the input/output line, and the P-type doped region of the second through-silicon via structure is electrically connected to a ground line.

### BRIEF DESCRIPTION OF THE DRAWINGS

FIGS. 1 and 5A illustrates an electrostatic discharge (ESD) protection circuit of a circuit, in accordance with some embodiments of the present disclosure.

FIG. 2 illustrates a package structure of a three-dimensional circuit, in accordance with some embodiments of the present disclosure.

FIGS. 3A to 3E illustrate schematic cross-sectional views corresponding to different intermediate stages of manufacturing a through-silicon via structure, in accordance with some embodiments of the present disclosure.

FIG. 4 illustrates a top view of a through-silicon via structure, in accordance with some embodiments of the present disclosure.

FIG. 5B illustrates a connection configuration diagram of through-silicon via structures in an electrostatic discharge protection circuit, in accordance with some embodiments of the present disclosure.

### DETAILED DESCRIPTION OF THE INVENTION

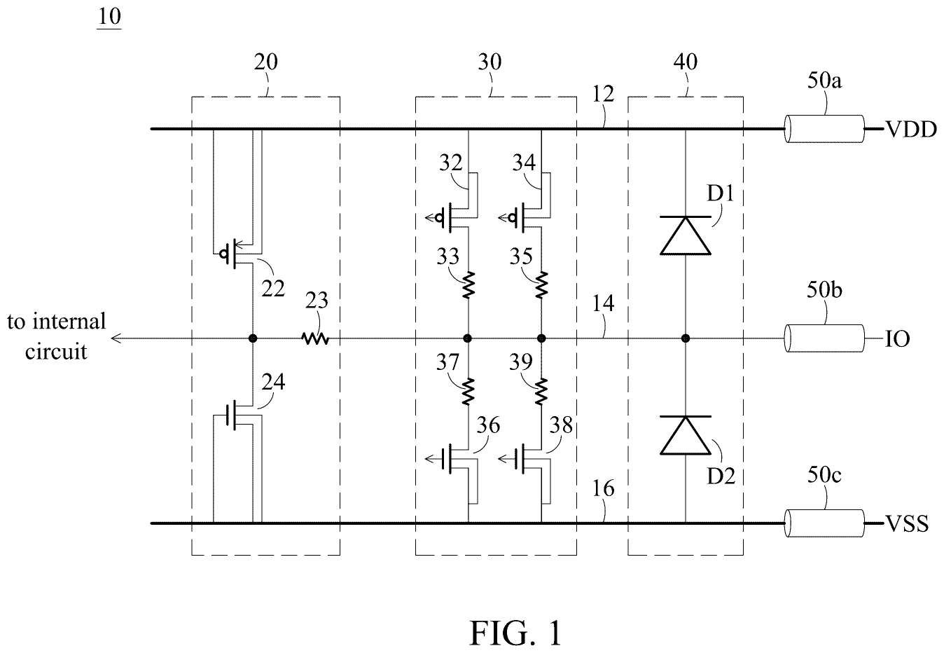

FIG. 1 illustrates an electrostatic discharge (ESD) protection circuit 10 of a circuit. The electrostatic discharge protection circuit 10 is used to provide electrostatic discharge protection for input/output (I/O) pins of the circuit. The electrostatic discharge protection circuit 10 includes a primary protection unit 40, a secondary protection unit 20, and an output driving unit 30. The primary protection unit 40 includes a pull-up diode D1 and a pull-down diode D2. The anode of the pull-up diode D1 is coupled to a through-silicon via 50b through an input/output line 14, and the cathode of pull-up diode D1 is coupled to a through-silicon via 50a through a power line 12. The anode of the pull-down diode D2 is coupled to a through-silicon via 50c through a ground line 16, and the cathode of pull-down diode D2 is coupled to the through-silicon via 50b through the input/output line 14. In the circuit, the power signal VDD from other wafers, dies, or substrates may enter the power line 12 through the through-silicon via 50a. In addition, the ground signal VSS from other wafers, dies, or substrates may enter the ground line 16 through the through-silicon via 50c. In the input mode, the input/output signal IO from other wafers, dies, or substrates may enter the input/output line 14 through the through-silicon via 50b. In the output mode, the input/output signal IO from the internal circuit an on the input/output line 14 may be transmitted to other wafers, dies, or substrates through the through-silicon via 50b.

The secondary protection unit 20 includes a P-type transistor 22, an N-type transistor 24, and a resistor 23. The secondary protection unit 20 is coupled to the input/output line 14 through the resistor 23. The output driving unit 30 includes P-type transistors 32 and 34, N-type transistors 36 and 38, and resistors 33, 35, 37, and 39. In the electrostatic discharge protection circuit 10, the circuit of the secondary protection unit 20 and the output driving unit 30 is an embodiment, and the actual circuit configuration can be modified according to different applications of the input/output pins of the circuit.

When an electrostatic discharge event of positive charge occurs at the input/output pin of the circuit, the electrostatic current from the input/output pin will flow from the through-silicon via 50b to the through-silicon via 50a through the pull-up diode D1. When an electrostatic discharge event of negative charge occurs at the input/output pin of the circuit, the electrostatic current from the input/output pin will flow from the through-silicon via 50b to the through-silicon via 50c through the pull-down diode D2. In order to increase the capability of the electrostatic discharge protection, the pull-up diode D1 and the pull-down diode D2 need to be designed to be large in size. In a traditional electrostatic discharge protection circuit, the layout area of the pull-up diode D1 and the pull-down diode D2 will be greater than the layout area of one through-silicon via.

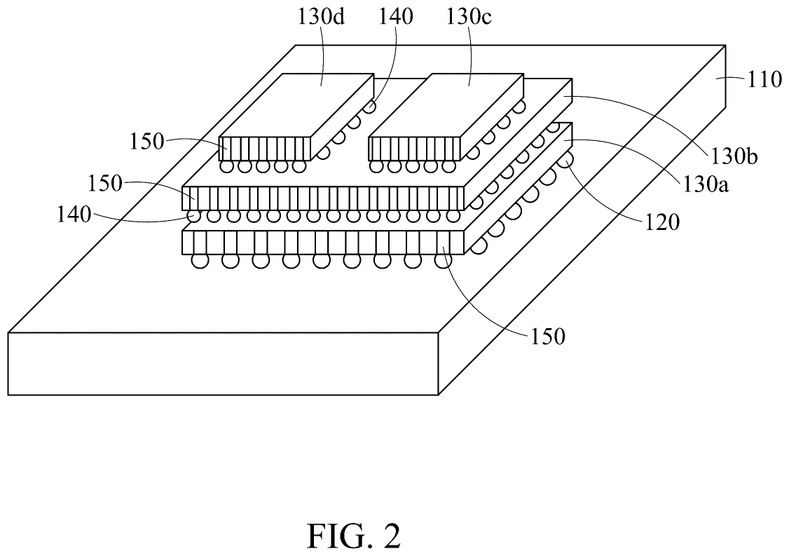

FIG. 2 illustrates a package structure of a three-dimensional circuit 100. In circuit 100, through-silicon via structures 150 of a die (or wafer) 130c and a die (or wafer) 130d are connected to a die (or wafer) 130b through micro bumps 140. Moreover, through-silicon via structures 150 of the die 130b are connected to a die (or wafer) 130a through the micro bumps 140. Furthermore, through-silicon via structures 150 of the die 130a are connected to the package substrate 110 through bumps 120, so as to be connected to the corresponding pins or bonding pads (not shown).

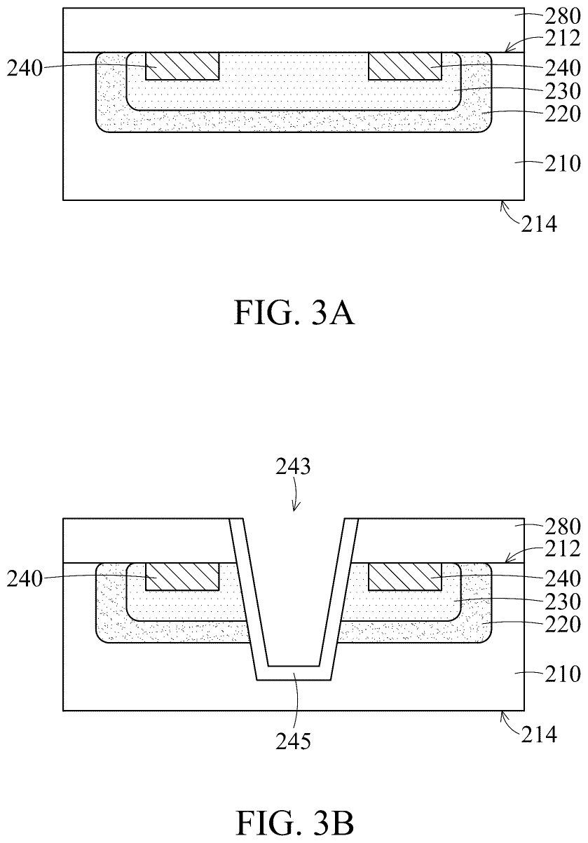

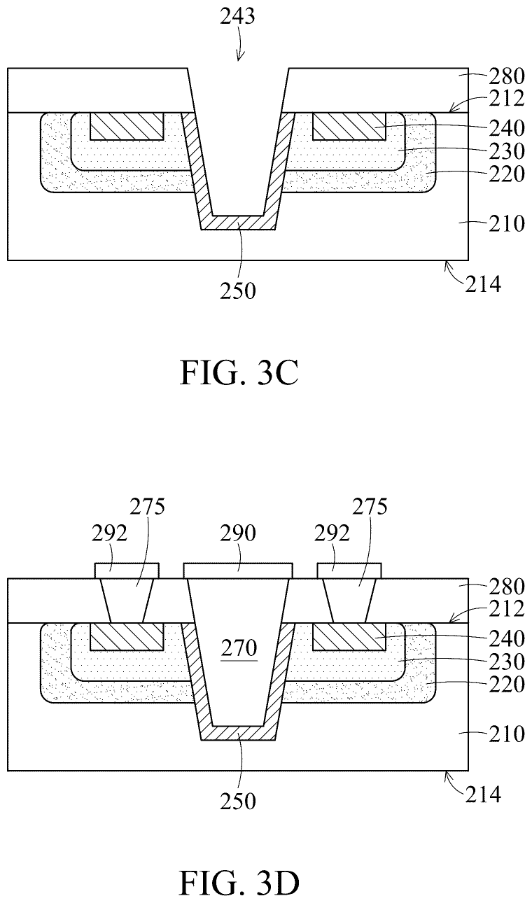

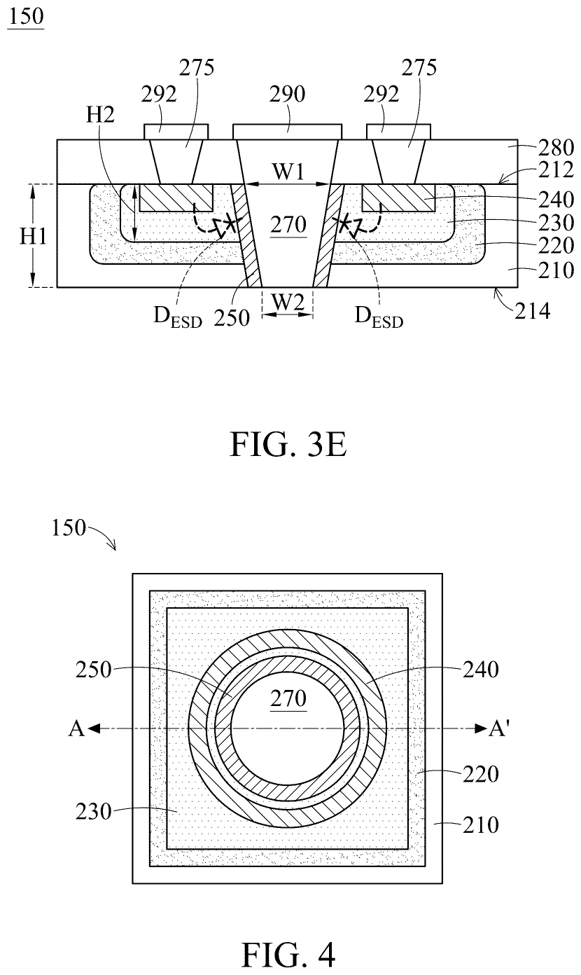

FIGS. 3A to 3E illustrate schematic cross-sectional views corresponding to different intermediate stages of manufacturing the through-silicon via structures 150. The through-silicon via structure 150 includes through-silicon vias combined with electrostatic discharge protection diodes. Therefore, compared with the through-silicon vias 50a, 50b, and 50c shown in FIG. 1, the through-silicon via structure 150 has better capability of electrostatic discharge protection.

Referring to FIG. 3A, a substrate 210 is provided. The material of the substrate 210 may include, for example, a semiconductor material. The substrate 210 includes silicon, gallium arsenide, gallium nitride, germanium silicide, or combinations thereof. Alternatively, the substrate 210 is a substrate of silicon-on-insulator. The substrate 210 has a first surface 212 and a second surface 214, and the second surface 214 is opposite to the first surface 212. For example, the first surface 212 is the upper surface of the substrate 210, and the second surface 214 is the lower surface of the substrate 210.

A deep N-type well region (DNW) 220 is formed in the substrate 210, and a P-type well region (PW) 230 is formed in the deep N-type well region 220. The P-type doped region (P+) 240 is formed by performing a doping process on the P-type well region 230. The upper surfaces of the deep N-type well region 220, the P-type well region 230, and the P-type doped region 240 are coplanar with the first surface 212 of the substrate 210. In the applications where the same signal is applied to the substrate 210 and the P-type doped region 240, the deep N-type well region 220 may be omitted from the through-silicon via structure 150.

A dielectric hard mask layer 280 is formed over the first surface 212 of the substrate 210. The dielectric hard mask layer 280 is formed of a dielectric material, such as silicon oxide (SiO), silicon oxynitride (SiON), silicon nitride (SiN), and/or other suitable dielectric materials. The dielectric hard mask layer 280 is formed from tetraethyl orthosilicate (TEOS) oxide, the dielectric hard mask layer 280 may be an inter-layer dielectric (ILD).

Referring to FIG. 3B, an etching process is performed to form the opening 243, and a liner 245 is formed in the opening 243, liner 245 may include titanium, titanium nitride, tantalum, tantalum nitride, or the like. The opening 243 and the liner 245 extend from the dielectric hard mask layer 280 to the substrate 210, and penetrate through the P-type well region 230 and the deep N-type well region 220.

Referring to FIG. 3C, the liner 245 is removed, and a doping process is performed on the opening 243 to form an N-type doped region (N+) 250. Therefore, the N-type doped region 250 extends from the first surface 212 of the substrate 210 to the substrate 210.

Referring to FIG. 3D, a conductive material is formed in the opening 243 to form a through-silicon via 270. The material of the through-silicon via 270 may include copper, copper alloy, silver, gold, tungsten, cobalt, aluminum, nickel, and the like. Moreover, the contacts 275 are formed in the dielectric hard mask layer 280 and over the P-type doped region 240. The contacts 275 are formed of a conductive material selected from the group consisting of tungsten, aluminum, copper, titanium, tantalum, titanium nitride, tantalum nitride, alloys thereof, and/or multilayers thereof. The formation of the contacts 275 may include forming a plurality of contact openings in the dielectric hard mask layer 280, filling the contact openings with conductive material, and performing a planarization process (e.g., chemical mechanical polishing (CMP)). The top surfaces of the contacts 275 and the through-silicon via 270 are level with the top surface of the dielectric hard mask layer 280.

An interconnect structure is formed over the dielectric hard mask layer 280. For the purpose of simplicity, the interconnection structure only shows metal lines 290 and 292 formed in the lowest metal layer. The metal line 290 is formed over the through-silicon via 270, and the metal lines 292 are formed over the contacts 275. The through-silicon via 270 penetrates through the dielectric hard mask layer 280 and contacts the metal line 290, so that the metal line 290 is electrically connected to the through-silicon via 270. In addition, the metal lines 292 are electrically connected to the P-type doped region 240 through the contacts 275.

Referring to FIG. 3E, a thinning process is performed on the second surface 214 of the substrate 210. The thinning process may include planarization process (chemical mechanical polishing), etching-back process, or a combination thereof. The substrate 210 may be thinned to reduce the length of the through-silicon via 270. The through-silicon via 270 penetrates the substrate 210 by a thickness H1 that is approximately 50 micrometers (μm), that is, the thickness of the substrate 210 from the first surface 212 to the second surface 214 is the thickness H1. For the through-silicon via 270, the size along the direction of the first surface 212 of the substrate 210 is larger than the size along the direction of the second surface 214 of the substrate 210, that is, length W1>length W2. Alternatively, for the through-silicon via 270, the size along the direction of the first surface 212 of the substrate 210 is equal to the size along the direction of the second surface 214 of the substrate 210, that is, length W1=length W2.

In the through-silicon via 270, the P-type well region 230 and the deep N-type well region 220 are separated from the through-silicon via 270 by the N-type doped region 250. In addition, the junction between the P-type well region 230 and the N-type doped region 250 will form an electrostatic discharge protection diode D_{ESD}. When the thickness H2 of the P-type well region 230 increases, the junction of the electrostatic discharge protection diode D_{ESD} also increases. It is noted that, in the circuit, the voltage applied to the metal line 290 is greater than the voltage applied to the metal lines 292.

FIG. 4 illustrates a top view of the through-silicon via structure 150. The cross-sectional view of the through-silicon via structure 150 along the line A-A′ can be referred to FIG. 3E. In FIG. 4, the configuration of the contacts 275 and the metal lines 290 and 292 is omitted to simplify the description.

Referring to FIGS. 3E and 4 simultaneously, the through-silicon via 270 is disposed in the center of the through-silicon via structure 150, the through-silicon via 270 has a circular shape in the layout. Alternatively, the through-silicon via 270 may have a polygonal shape in the layout, such as a quadrilateral, a hexagon, an octagon, and the like. Moreover, when the side length of the through-silicon via 270 in the layout increases, the PN junction of the electrostatic discharge protection diode D_{ESD} also increases. Furthermore, the through-silicon via 270 extends from the upper surface of the dielectric hard mask layer 280 to the second surface 214 of the substrate 210.

The N-type doped region 250 forms a ring shape in the top view (layout). The through-silicon via 270 is completely surrounded by the N-type doped region 250, and the through-silicon via 270 is in direct contact with the N-type doped region 250. The N-type doped region 250 extends from the first surface 212 of the substrate 210 to the second surface 214 of the substrate 210, that is, the N-type doped region 250 penetrates through the substrate 210.

The P-type doped region 240 forms a ring shape in the top view (layout), and the N-type doped region 250 is surrounded by the P-type doped region 240, the N-type doped region 250 is also surrounded by the P-type well region 230, and the N-type doped region 250 and the P-type doped region 240 are separated by the P-type well region 230. In addition, the P-type well region 230 is surrounded by the deep N-type well region 220. Alternatively, the P-type doped region 240 is in contact with the N-type doped region 250.

The upper surfaces of the deep N-type well region 220, the P-type well region 230, the P-type doped region 240, and the N-type doped region 250 are coplanar with the first surface 212 of the substrate 210. The lower surface of the P-type doped region 240 is higher than the lower surface of the P-type well region 230, and the lower surface of the P-type well region 230 is higher than the lower surface of the deep N-type well region 220. In other words, the lower surface of the deep N-type well region 220 is between the lower surface of the P-type well region 230 and the second surface 214 of the substrate 210. The lower surfaces of the N-type doped region 250 and the through-silicon via 270 are coplanar with the second surface 214 of the substrate 210.

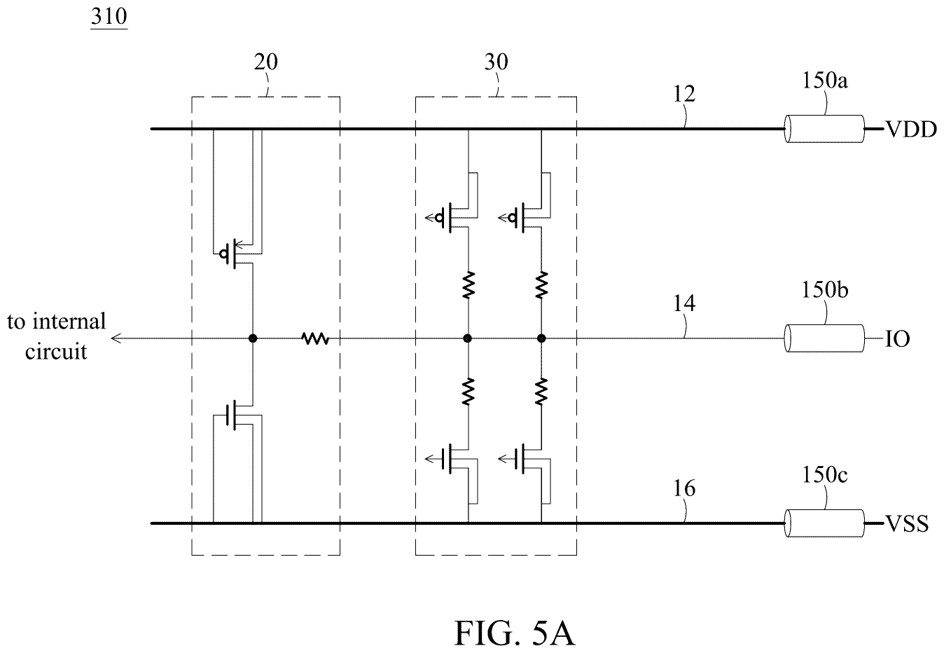

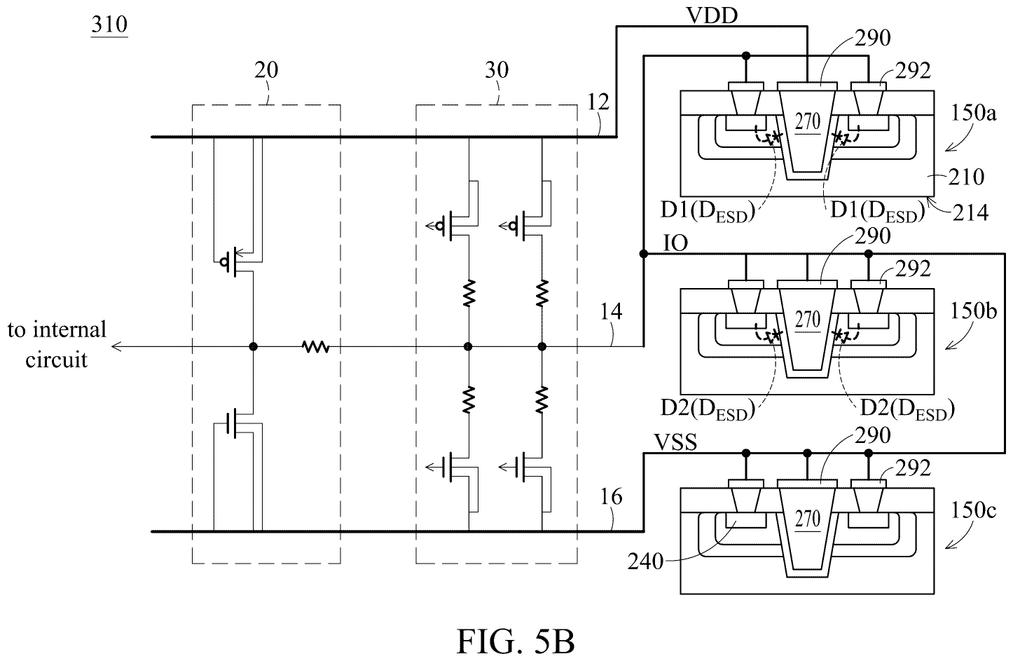

FIG. 5A illustrates an electrostatic discharge protection circuit 310. The electrostatic discharge protection circuit 310 is used to provide electrostatic discharge protection for the input/output pins of the circuit. The electrostatic discharge protection circuit 310 includes a secondary protection unit 20 and an output driving unit 30. In the circuit, the power signal VDD from other wafers, dies, or substrates may enter the internal circuit (not shown) of the circuit through the through-silicon via structure 150a and the power line 12. Moreover, the ground signal VSS from other wafers, dies, or substrates may enter the internal circuit of the circuit through the through-silicon via structure 150c and the ground line 16. In the input mode, the input/output signal IO from other wafers, dies, or substrates may enter the internal circuitry of the circuit through the through-silicon via structure 150b and the input/output line 14. In the output mode, the input/output signal IO from the internal circuit may be transmitted to other wafers, dies, or substrates through the input/output line 14 and the through-silicon via structure 150b. As described above, the through-silicon via structures 150a, 150b, and 150c include through-silicon vias 270 combined with the electrostatic discharge protection diodes D_{ESD}.

Compared with the electrostatic discharge protection circuit 10 shown in FIG. 1, the electrostatic discharge protection circuit 310 shown in FIG. 5A does not include the primary protection unit 40. In the electrostatic discharge protection circuit 310 shown in FIG. 5A, the pull-up diode D1 and the pull-down diode D2 are provided by the electrostatic discharge protection diodes D_{ESD} of the through-silicon via structures 150a and 150b, respectively.

FIG. 5B illustrates a connection configuration diagram of the through-silicon via structures 150a, 150b, and 150c in the electrostatic discharge protection circuit 310. The fabrication process of through-silicon via structures 150a, 150b, and 150c is as described in FIG. 3A to 3E.

In FIG. 5B, the metal line 290 of the through-silicon via structure 150a is coupled to the power line 12, and the metal line 292 of the through-silicon via structure 150a is coupled to the input/output line 14. In the through-silicon via structure 150a, the through-silicon via 270 is electrically connected to the power terminal of other wafers, dies, or substrates through bumps or micro-bumps (not shown) located on the second surface 214 of the substrate 210. In the through-silicon via structure 150a, the anode of the electrostatic discharge protection diode D_{ESD} is coupled to the input/output line 14, and the cathode of the electrostatic discharge protection diode D_{ESD} is coupled to the power line 12. The electrostatic discharge protection diode D_{ESD} of the through-silicon via structure 150a may function as the pull-up diode D1. In other words, in the electrostatic discharge protection circuit 310, the pull-up diode D1 is integrated in the through-silicon via structure 150a.

The metal line 290 of the through-silicon via structure 150b is coupled to the input/output line 14, and the metal line 292 of the through-silicon via structure 150b is coupled to the ground line 16. In the through-silicon via structure 150b, the through-silicon via 270 is electrically connected to the input/output terminal of other wafers, dies, or substrates through bumps or micro-bumps (not shown) located on the second surface 214 of the substrate 210. The substrate 210 is a P-type substrate and is coupled to the ground. In the through-silicon via structure 150b, the substrate 210 and the P-type doped region 240 are simultaneously coupled to the ground terminal, and the deep N-type well region 220 can be omitted from the through-silicon via structure 150b. In the through-silicon via structure 150b, the anode of the electrostatic discharge protection diode D_{ESD} is coupled to the ground line 16, and the cathode of the electrostatic discharge protection diode D_{ESD} is coupled to the input/output line 14. Therefore, the electrostatic discharge protection diode D_{ESD} of the through-silicon via structure 150b may function as the pull-down diode D2. In other words, in the electrostatic discharge protection circuit 310, the pull-down diode D2 is integrated in the through-silicon via structure 150b.

The metal lines 290 and 292 of the through-silicon via structure 150c are coupled to the ground line 16. In the through-silicon via structure 150c, the through-silicon via 270 is electrically connected to the ground terminal of other wafers, dies, or substrates through bumps or micro-bumps (not shown) on the second surface 214 of the substrate 210.

In the through-silicon via structure 150c, the anode and the cathode of the electrostatic discharge protection diode D_{ESD} are coupled together to the ground line 16. Therefore, the electrostatic discharge protection diode D_{ESD} of the through-silicon via structure 150c will not turn-on. The through-silicon via structure 150c may be replaced by the through-silicon via 50c shown in FIG. 1.

In the embodiments of the present disclosure, by using the N-type doped region 250 to surround the through-silicon via 270, an electrostatic discharge protection diode D_{ESD} with a large junction can be formed between the P-type well region 230 and the N-type doped region 250. Compared with the traditional through-silicon via that requires additional large-area pull-up diode and pull-down diode to provide electrostatic discharge protection, the through-silicon via structure 150 can combine the electrostatic discharge protection diode D_{ESD} with the through-silicon via 270, thereby significantly reducing the layout area of the circuit, so as to improve the usage efficiency of the wafer area.

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A through-silicon via structure, comprising:
a substrate, having a first surface and a second surface, wherein the second surface is opposite to the first surface;
a through-silicon via, extending from the first surface to the second surface of the substrate;
an N-type doped region, surrounding the through-silicon via and extending from the first surface to the second surface of the substrate;
a P-type well region, formed in the substrate and surrounding the N-type doped region; and
a P-type doped region, formed in the P-type well region and surrounding the N-type doped region, wherein a junction of the P-type well region and the N-type doped region forms an electrostatic discharge protection diode.

2. The through-silicon via structure as claimed in claim 1, wherein the P-type doped region is separated from the N-type doped region by the P-type well region.

3. The through-silicon via structure as claimed in claim 1, further comprising:
a deep N-type well region, formed in the substrate and surrounding the P-type well region,
wherein an upper surface of the deep N-type well region and the first surface of the substrate are coplanar, and wherein a lower surface of the deep N-type well region is between a lower surface of the P-type well region and the second surface of the substrate.

4. The through-silicon via structure as claimed in claim 3, wherein the upper surface of the deep N-type well region, an upper surface of the P-type well region, and an upper surface of the P-type doped region are coplanar.

5. The through-silicon via structure as claimed in claim 3, wherein the deep N-type well region and the P-type well region are separated from the through-silicon via by the N-type doped region.

6. The through-silicon via structure as claimed in claim 1, further comprising:
a dielectric hard mask layer, formed over the first surface of the substrate; and
a metal layer, formed over the dielectric hard mask layer,
wherein the through-silicon via penetrates through the dielectric hard mask layer and is in contact with a first metal line of the metal layer.

7. The through-silicon via structure as claimed in claim 6, further comprising:
a contact, formed in the dielectric hard mask layer and located over the P-type doped region,
wherein a second metal line of the metal layer is electrically connected to the P-type doped region through the contact.

8. The through-silicon via structure as claimed in claim 7, wherein when the first metal line is electrically connected to an input/output line, the second metal line is electrically connected to a ground line, and the electrostatic discharge protection diode is a pull-down diode between the input/output line and the ground line.

9. The through-silicon via structure as claimed in claim 1, wherein a first length of the through-silicon via along the first surface of the substrate is greater than a second length of the through-silicon via along the second surface of the substrate.

10. The through-silicon via structure as claimed in claim 1, further comprising a micro bump formed on the second surface of the substrate and electrically connected to the through-silicon via.

11. A circuit, comprising:
a substrate, having a first surface and a second surface, wherein the second surface is opposite to the first surface; and
a plurality of through-silicon via structures, each comprising:
a through-silicon via, extending from the first surface to the second surface of the substrate;
an N-type doped region, surrounding the through-silicon via and extending from the first surface to the second surface of the substrate;
a P-type well region, formed in the substrate and surrounding the N-type doped region; and
a P-type doped region, formed in the P-type well region and surrounding the N-type doped region,
wherein a junction of the P-type well region and the N-type doped region forms an electrostatic discharge protection diode,
wherein the through-silicon via of a first through-silicon via structure of the plurality of through-silicon via structures is electrically connected to a power line, and the P-type doped region of the first through-silicon via structure is electrically connected to an input/output line,
wherein the through-silicon via of a second through-silicon via structure of the plurality of through-silicon via structures is electrically connected to the input/output line, and the P-type doped region of the second through-silicon via structure is electrically connected to a ground line.

12. The circuit as claimed in claim 11, wherein the through-silicon via and the P-type doped region of a third through-silicon via structure of the plurality of through-silicon via structures are electrically connected to the ground line.

13. The circuit as claimed in claim 11, wherein the electrostatic discharge protection diode of the first through-silicon via structure is a pull-up diode between the power line and the input/output line.

14. The circuit as claimed in claim 11, wherein in each of the plurality of through-silicon via structures, an upper surface of the P-type well region and the first surface of the substrate are coplanar, and a lower surface of the P-type well region is higher than the second surface of the substrate.

15. The circuit as claimed in claim 11, wherein in each of the plurality of through-silicon via structures, the P-type doped region is separated from the N-type doped region by the P-type well region.

16. The circuit as claimed in claim 11, wherein each of the plurality of through-silicon via structures further comprises:
a deep N-type well region, formed in the substrate and surrounding the P-type well region,
wherein an upper surface of the deep N-type well region and the first surface of the substrate are coplanar, and wherein a lower surface of the deep N-type well region is between a lower surface of the P-type well region and the second surface of the substrate.

17. The circuit as claimed in claim 16, wherein in each of the plurality of through-silicon via structures, the upper surface of the deep N-type well region, an upper surface of the P-type well region, and an upper surface of the P-type doped region are coplanar.

18. The circuit as claimed in claim 16, wherein in each of the plurality of through-silicon via structures, the deep N-type well region and the P-type well region are separated from the through-silicon via by the N-type doped region.

19. The circuit as claimed in claim 11, further comprising:
a dielectric hard mask layer, formed over the first surface of the substrate; and
a metal layer, formed over the dielectric hard mask layer,
wherein in each of the plurality of through-silicon via structures, the through-silicon via penetrates through the dielectric hard mask layer and is in contact with a first metal line of the metal layer.

20. The circuit as claimed in claim 19, comprising:
wherein the through-silicon via of the first through-silicon via structure is electrically connected to the power line through the first metal line of the first through-silicon via structure, and
wherein the through-silicon via of the second through-silicon via structure is electrically connected to the input/output line through the first metal line of the second through-silicon via structure.
